(19) United States
(12) Patent Application Publication
(10) Pub. No.: US 2014/0164688 A1
(43) Pub. Date: Jun. 12, 2014

(54) SOC SYSTEM AND METHOD FOR OPERATING THE SAME

(71) Applicant: SAMSUNG ELECTRONICS CO., LTD., Suwon-si (KR)

(72) Inventors: KI-TAE LEE, Seongnam-si (KR); SANG-HWA JIN, Seongnam-si (KR); SANG-JONG KIM, Hwaseong-si (KR)

(73) Assignee: SAMSUNG ELECTRONICS CO., LTD., Suwon-si (KR)

(21) Appl. No.: 14/089,961

(22) Filed: Nov. 26, 2013

(30) Foreign Application Priority Data
Dec. 7, 2012 (KR) 10-2012-0142017

(51) Int. Cl. G11C 7/10

(52) U.S. Cl. CPC G11C 7/1015
USPC 711/104

(57) ABSTRACT

A SOC system includes a central processing unit; a memory management unit receiving a virtual address from the central processing unit and converting the virtual address into a physical address; a main memory implemented by a volatile memory and directly accessed through the physical address converted by the memory management unit; and a storage implemented by a nonvolatile memory separate from the main memory and including a first area directly accessed through the physical address converted by the memory management unit.

### CROSS-REFERENCE TO RELATED APPLICATIONS

This application claims priority to Korean Patent Application No. 10-2012-0142017, filed on Dec. 7, 2012 in the Korean Intellectual Property Office, the disclosure of which is incorporated by reference in its entirety herein.

### BACKGROUND

1. Technical Field

Embodiments of the present inventive concept relate to a SOC (System On Chip) system and a method for operating the same.

2. Discussion of Prior Art

A dynamic random-access memory (DRAM) is a type of random-access memory that stores each bit of data in a separate capacitor within an integrated circuit. The capacitor can either be charged in one state or discharged in a second state, and these two states represent two values of a bit. Since capacitors leak charge, the information eventually fades unless the capacitor charge is refreshed periodically.

A DRAM may be used as a main memory of a computer. However, a computer that uses a DRAM memory may consume a great deal of power and make it difficult to backup information.

### SUMMARY

At least one embodiment of the present inventive provides a SOC system, which can perform high-speed operation without the necessity of separate memory loading time.

At least one embodiment of the inventive concept provides a method for operating a SOC system, which can perform high-speed operation without the necessity of separate memory loading time.

According to an exemplary embodiment of the present inventive concept, there is provided a SOC system including: a central processing unit; a memory management unit configured to receive a virtual address from the central processing unit and convert the virtual address into a physical address; a main memory implemented by a volatile memory and directly accessed through the physical address converted by the memory management unit; and a storage implemented by a nonvolatile memory separate from the main memory and including a first area directly accessed through the physical address converted by the memory management unit.

According to an exemplary embodiment of the present inventive concept, there is provided a method for operating a SOC system. The method includes: storing an execution file in a first area of a storage implemented by a nonvolatile memory in the form of a binary file; and during execution of the execution file, configuring the first area of the storage as an area that can be directly accessed by a central processing unit, and then executing the execution file.

According to an exemplary embodiment of the present inventive concept, there is provided a SOC system including a central processing unit (CPU), a memory management unit (MMU), a translation lookaside buffer (TLB), a main memory, and a virtual memory. The MMU is configured to receive a virtual address from the CPU and convert the virtual address into a physical address. The TLB is configured to convert the virtual address into a physical address when virtual memory is needed. The main memory includes a volatile memory directly accessed through the physical memory converted by the MMU. The virtual memory includes a nonvolatile memory having a first area directly accessed through the physical address converted by the TLB.

### BRIEF DESCRIPTION OF THE DRAWINGS

The inventive concept will be more apparent from the following detailed description of the exemplary embodiments taken in conjunction with the accompanying drawings, in which:

FIG. 1 is a block diagram illustrating a SOC system according to an exemplary embodiment of the present inventive concept;

FIG. 2 is a flowchart explaining a method of operating a SOC system according to an exemplary embodiment of the present inventive concept;

FIGS. 3 and 4 are diagrams explaining the operation of a SOC system according to an exemplary embodiment of the present inventive concept;

FIG. 5 is a diagram explaining the operation of a SOC system according to an exemplary embodiment of the present inventive concept;

FIG. 6 is a block diagram illustrating a SOC system according to an exemplary embodiment of the present inventive concept;

FIG. 7 is a block diagram illustrating a computing system that includes the main memory and storage of the SOC system according to an exemplary embodiment of the present inventive concept;

FIG. 8 is a block diagram illustrating an electronic system including a SOC system according to an exemplary embodiment of the present inventive concept; and

FIG. 9 is a view illustrating an application example of the electronic system of FIG. 8 applied to a smart phone.

### DETAILED DESCRIPTION

The present inventive concept and methods of accomplishing the same may be understood more readily by reference to the following detailed description of exemplary embodiments thereof and the accompanying drawings. The present inventive concept may, however, be embodied in many different forms and should not be construed as being limited to the exemplary embodiments set forth herein. In the drawings, the thickness of layers and regions may be exaggerated for clarity.

It will be understood that when an element or layer is referred to as being “on” or “connected to” another element or layer, it can be directly on or connected to the other element or layer or intervening elements or layers may be present.

The use of the terms “a” and “an” and “the” and similar referents in the context of describing the invention (especially in the context of the following claims) are to be construed to cover both the singular and the plural, unless otherwise indicated herein or clearly contradicted by context.

The methods of the inventive concept described below can be embodied as computer readable codes on a computer readable recording medium. The medium is any data storage device that can store data which can be thereafter read by a computer system. For example, the medium may include program storage device such as a hard disk, magnetic floppy disk, RAM, ROM, CD ROM, etc., and be executable by and device or machine comprising suitable architecture, such as a general purpose digital computer having a processor, memory, and input/output interfaces.

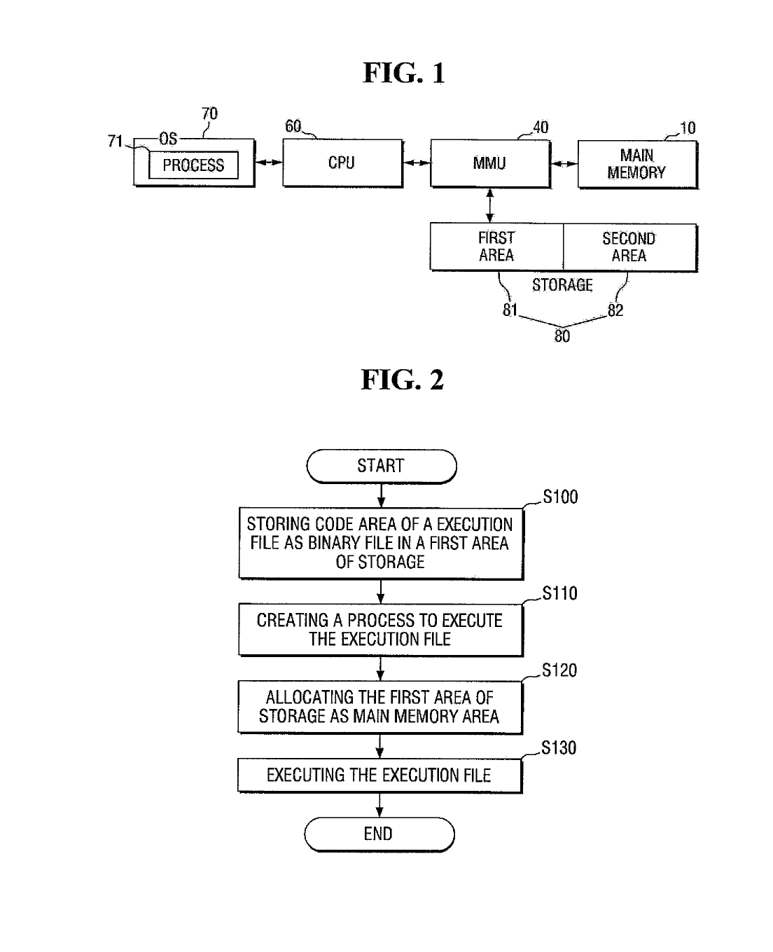

Hereinafter, a SOC system according to an exemplary embodiment of the present inventive concept will be described with reference to FIG. 1.

FIG. 1 is a block diagram illustrating the SOC system according to an exemplary embodiment of the present inventive concept.

Referring to FIG. 1, the SOC (System On Chip) system includes a main memory 10, an MMU (Memory Management Unit) 40, a CPU (Central Processing Unit) 60, a storage 80, and an operating system OS 70. The operating system 70 may be executed by the CPU 60 and loaded from another memory (not shown).

In an exemplary embodiment, the main memory 10 stores data that is used for an operation of the central processing unit 60. For example, when the central processing unit 60 operates to perform (e.g., execute) a process 71 (e.g., a computer program), the main memory 10 loads the data that is necessary for an operation from the storage 80 or the like, and provides the data that is necessary for the operation to the central processing unit 60.

In an exemplary embodiment of the present inventive concept, the main memory 10 is implemented by a volatile memory. The main memory 10 may be implemented by, for example, a DRAM (Dynamic Random Access Memory), an SRAM (Static Random Access Memory), or an embedded RMA, but the present inventive concept is not limited thereto.

The OS 70 may generate the process 71 that is necessary for execution of file data stored in the storage 80 or the like. To perform the process 71 generated as above, the OS 70 may command the central processing unit 60 to operate and process the data that is addressed by a VA (Virtual Address), and thus the central processing unit 60 may provide the virtual address of the data that is necessary for the operation and processing to the memory management unit 40.

In an exemplary embodiment, the memory management unit 40, which has received the virtual address from the central processing unit 60, converts the virtual address provided from the central processing unit 60 into a PA (Physical Address) that can be directly referred to on the main memory 10 or a first area 81 of the storage 80 with reference to a page table (not illustrated). Although the page table is not illustrated in FIG. 1, in an exemplary embodiment of the present inventive concept, the page table may be stored in the main memory 10 or the first area 81 of the storage 80.

The storage 80 may be provided with a mass storage space in comparison to the main memory 10, and may be implemented by, for example, a nonvolatile memory. Examples of such a nonvolatile memory include an MRAM (Magnetic Random Access Memory), a PRAM (Phase-change Random Access Memory), an FRAM (Ferroelectric Random Access Memory), and the like, but the present inventive concept is not limited thereto.

In an exemplary embodiment where the storage 80 is implemented by the MRAM, the MRAM using a magnetic material element has both the DRAM characteristic in which electric information can be rapidly taken out and the magnetic recording characteristic in which the information can be kept for a long term, and thus the SOC system according to this embodiment can be operated at a higher speed.

An example of the storage 80 implemented by the nonvolatile memory may be a SSD (Solid State Drive), but the present inventive concept is not limited thereto. In an exemplary embodiment of the present inventive concept, the storage 80 is a HDD (Hard Disk Drive).

Referring again to FIG. 1, the storage 80 includes the first area 81 and a second area 82. In the first area 81 of the storage 80, a specific area having a predetermined characteristic of an execution file is loaded in the form of a binary file. In an exemplary embodiment, when external data is stored in the first area 81 of the storage 80, the data is not stored with a file structure as is the case when storing the data in general storage. For example, the data may be stored in the form of a binary file (e.g., execution file) in which a source code of the execution file is compiled and linked as in the case of loading the data to the main memory 10.

For example, if a binary file is opened as if it is a text file, it will not be understandable by a human operator as human readable text. For example, one can use a computer program written in a computer language (e.g., C) to write several human readable characters (e.g., “ABC”, “DOG”, etc.) into a binary file. The resulting binary file does not include the human readable characters but binary representations of these characters. For example, the hexadecimal code 41 (or 01000001 in binary) represents a capital “A” in standard ASCII notation. However, a computer program can be written to read back the stored data into variables that can be output using a print function to a printer or presented to a display using a display function. For example, if the binary file includes 1 byte of binary data, and a variable is a 1 byte character, a binary read operation performed on the binary file can be used to store the 1 byte character into the variable, and a print function (e.g., printf) can be used to display the human readable version of the binary data. In another example, computer executable commands are written into an executable binary file (e.g., an execution file). The resulting executable binary file does not include human readable commands but binary representations of these commands/instructions that are executable by a processor (e.g., CPU 60).

In an exemplary embodiment of the present inventive concept, the predetermined characteristic is a read-only characteristic that is necessary for an operation of the process 71. For example, in the first area 81 of the storage 80, the specific area of the execution file having the read-only characteristic that is necessary for the operation of the process 71 is loaded in the form of a binary file.

Further, in an exemplary embodiment of the present inventive concept, the specific area of the execution file may be, for example, a code area of the execution file. For example, in the first area 81 of the storage, a code area (e.g., code segment) of the execution file having the read-only characteristic may be loaded in the form of a binary file. In an exemplary embodiment, the code area refers to a section of a program in an object file, which contains executable instructions.

When the execution file is executed, the first area 81 of the storage 80 is allocated (e.g., configured) by the OS 70 like the area of the main memory 10 that can be directly accessed by the memory management unit 40. For example, when the execution file is executed, the memory management unit 40 according to this embodiment directly accesses the main memory 10 which is implemented separately from the storage 80 and includes, for example, a volatile memory, and the first area 81 of the storage 80 which includes, for example, a nonvolatile memory such as an MRAM.

As described above, since the code area having the read-only characteristic has already been loaded in the first area 81 of the storage 80, the memory management unit 40 refers to and provides the code area to the central processing unit 60 without performing any additional work, and thus page swap between the main memory 10 and the storage 80 or the like becomes unnecessary.

Further, since the code area stored in the first area 81 of the storage 80 has the to read-only characteristic, an additional write operation never or rarely occurs in the first area 81 of the storage 80, and thus the operational performance of the whole system does not deteriorate even if the storage 80 is implemented by, for example, an MRAM.

In an exemplary embodiment of the present inventive concept, when the execution file is executed, the first area 81 of the storage 80 is used as a virtual memory. Such a virtual memory is a partial area of the storage space of the storage 80 that is used just like the main memory 10. The virtual memory of the storage 80 may be needed when the amount of data to be processed in the SOC system is excessive, such as in a multimedia environment or the like. For example, the main memory 10, by itself, may not be able to accommodate all the data that is required to execute a multimedia process. If the first area 81 of the storage 80 is used as the virtual memory, when the execution file is executed, for example, the configuration of the SOC system as described above may be modified so that a TLB (Transition Lookaside Buffer) directly accesses the first area 81 of the storage 80. In an exemplary embodiment, the MMU 40 includes the TLB. A TLB may be a cache that is used to improve virtual address translation speed. For example, a TLB can be used to map virtual addresses to physical addresses.

The second area 82 of the storage 80 according to this embodiment may be used in a similar manner to the storage of a general SOC system. For example, in the second area 82 of the storage 80, the remaining area of the execution file that is not stored in the first area 81 is stored. An example of such an area may be a data area (data segment) or a BSS area (BSS segment), but the present inventive concept is not limited thereto. In an exemplary embodiment, the data area contains global variables and static variables that are initialized by a programmer. The size of the data area may be determined by the values placed there by the programmer before the program was compiled. In an embodiment, the BSS starts at the end of the data area and contains all global variables and static variables that initialized to an initial value (e.g., 0), or do not have explicit initialization in source code. The data area and the BSS area of the execution file that is stored in the second area 82 of the storage 80 may be stored in the form of a file structure unlike the code area that is loaded in the form of a binary file in the first area 81 of the storage 80. In an exemplary embodiment, the contents of the file structure unlike the code area include human readable data (e.g., text).

Hereinafter, referring to FIGS. 2 to 4, the operation of the SOC system according to an exemplary embodiment of the present inventive will be described.

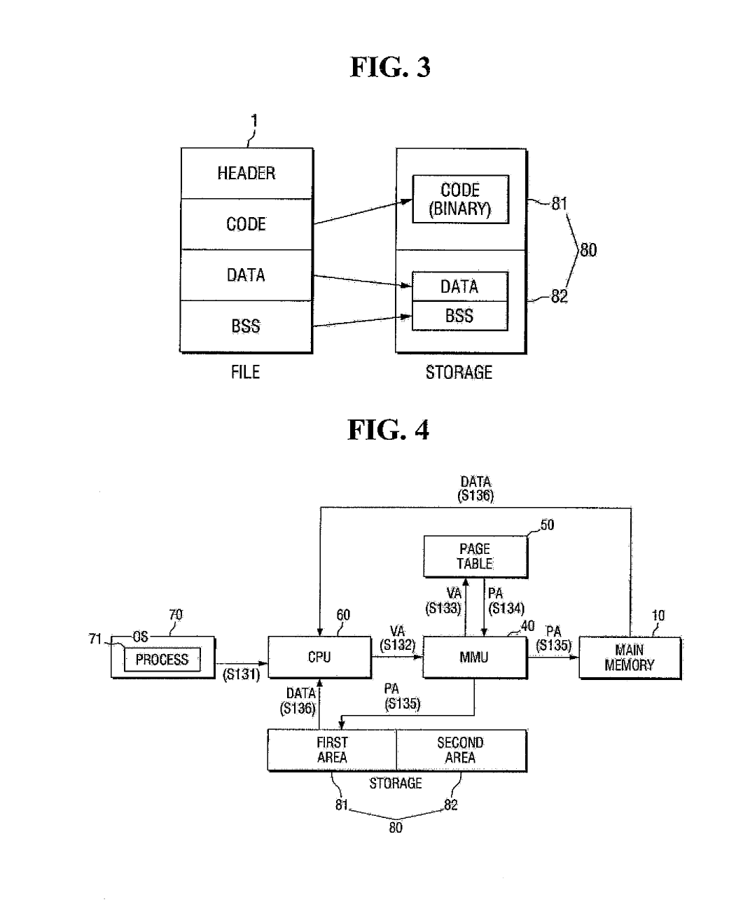

FIG. 2 is a flowchart explaining a method of operating the SOC system according to an exemplary embodiment of the present inventive concept. FIGS. 3 and 4 are diagrams explaining the operation of the SOC system according to an exemplary embodiment of the present inventive concept.

First, referring to FIG. 2, the code area of an execution file is stored in the first area of the storage (e.g., 81) in the form of a binary file (S100). For example, referring to FIG. 3, an execution file 1 includes a header, a code area, a data area, and a BSS area. When such an execution file 1 is stored in the storage 80, the code area of the execution file 1 is stored in the first area 81 of the storage 80 in a binary form, and the data area and the BSS area are stored in the second area 82 of the storage 80. In an exemplary embodiment, the code area of the execution file 1 has the read-only characteristic that is necessary for the operation of the process 71, and the data area and the BSS area of the execution file 1 has the read-write characteristic.

Referring again to FIG. 2, a process to execute the execution file is generated (S110). For example, referring to FIG. 1, the OS (Operating System) 70 generates the process 71 that performs the execution of the execution file 1 pre-stored in the storage 80 using a command that is provided from a user or the like.

Then, referring to FIG. 2, the first area of the storage (e.g., 81) is allocated as a main memory area (S120). For example, referring to FIG. 2, the OS 70 allocates the first area 81 of the storage 70 as an area like that of the main memory 10 that can be directly accessed by the memory management unit 40.

In an alternate embodiment, instead of configuring the first area as a main memory, it is configured as a virtual memory. For example, when the first area 81 of the storage 80 is used as the virtual memory, the OS 70 allocates (configures) the first area 81 of the storage 70 as a virtual memory area that can be directly accessed by the TLB (not illustrated).

Referring again to FIG. 2, the execution file is executed by the generated process (S130). For example, referring to FIG. 4, the OS 70 first requests that the central processing unit 60 performs the necessary operation (S131). Then, the central processing unit 60 transmits the virtual address VA of the data that is necessary for the operation to the memory management unit 40 (S132).

The memory management unit 40, which has received the virtual address VA from the central processing unit 60, obtains the physical address PA that corresponds to the virtual address VA (S134) with reference to the page table 50 or the like through the provided virtual address VA (S133). Thereafter, the memory management unit 40 searches the main memory 10 and the first area 81 of the storage 80 through the physical address PA (S135), and provides the data that is addressed by the physical address PA to the central processing unit 60 (S136). Then, the central processing unit 60 performs the operation with the provided data.

In the SOC system according to this embodiment as described above, since the code area having the read-only characteristic that is necessary for the operation of the process 71 has already been stored in the first area 81 of the storage 80 in the form of a binary file, the memory management unit 40 refers to and provides the code area to the central processing unit 60 without the necessity of any additional work. Accordingly, a page swap between the main memory 10 and the storage 80, which is performed when the data that is necessary for the operation of the central processing unit 60 is absent from the main memory 10, becomes unnecessary, and thus the operating speed of the SOC system can be improved.

If the first area 81 of the storage 80 is implemented by, for example, an MRAM, refresh becomes unnecessary, but a large quantity of write energy and write time are required in writing the data in the MRAM. However, as described above, since the code area having the read-only characteristic is stored in the first area 81 of the storage 80 of the SOC system according to this embodiment, an additional write operation rarely or never occurs in the first area 81 of the storage 80, and thus the operational performance of the whole system may not deteriorate even if the storage 80 is implemented by, for example, the MRAM.

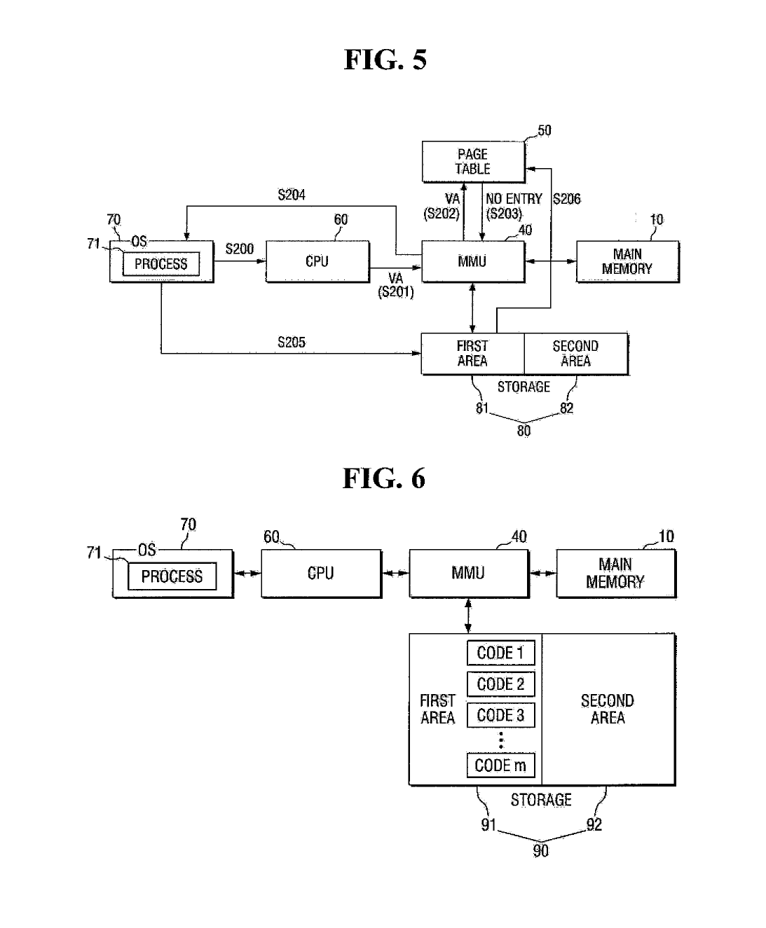

When a new execution file that has not yet been executed is newly stored in the storage 80, the memory management unit 40 may be unable to refer to the new execution file. However, even in this case, the whole SOC system according to this embodiment can operate at high speed by minimizing the execution time that is required for the operation. Hereinafter, referring to FIG. 5, this case will be described in more detail.

FIG. 5 is a diagram explaining the operation of a SOC system according to an exemplary embodiment of the present inventive concept.

Referring to FIG. 5, the OS 70 first requests that the central processing unit 60 performs an operation of the process 71 that is related to a new execution file (S200). Then, the central processing unit 60 transmits the virtual address VA of the data that is necessary for the operation to the memory management unit 40 (S201).

The memory management unit 40, which has received the virtual address VA from the central processing unit 60, refers to a page table 50 through the provided virtual address VA (S202). In this case, since the data that is addressed by the received virtual address VA is not present in the page table 50, it is not possible to return the physical address PA that corresponds to the received virtual address VA (S203).

Accordingly, the memory management unit 40 transfers the control authority to the OS 70 together with a message notifying that the physical address PA which corresponds to the received virtual address VA is unable to be found (S204). The OS 70, which has received the control authority, searches for the code area of the execution file that is newly loaded from the first area 81 of the storage 80 based on the virtual address VA which addresses the data that is necessary for the operation (S205), and based on this, updates the page table 50 (S206).

Once the page table 50 is updated as described above, the memory management unit 40 can access the newly added execution file. That is, a separate page swap operation between the main memory 10 and the storage 80 becomes unnecessary in the SOC system according to this embodiment. Through this operation, the SOC system according to this embodiment can operate at a higher speed.

Next, referring to FIG. 6, a SOC system according to an exemplary embodiment of the present invention will be described.

FIG. 6 is a block diagram illustrating a SOC system according to an exemplary embodiment of the present inventive concept.

Referring to FIG. 6, the SOC system includes a main memory 10, an MMU (Memory Management Unit) 40, a CPU (Central Processing Unit) 60, and a storage 90.

In the same manner as the above-described embodiment, the main memory 10 may store data that is used for the operation of the central processing unit 60. For example, when the central processing unit 60 operates for the execution of the process 71 by the OS 70, the main memory 10 loads the data that is necessary for the operation from the storage 90 or the like, and provides the data that is necessary for the operation of the central processing unit 60. In an exemplary embodiment of the present inventive concept, the main memory 10 is implemented by, for example, a DRAM (Dynamic Random Access Memory), an SRAM (Static Random Access Memory), or an embedded RMA, but the present inventive concept is not limited thereto.

The OS 70 may generate the process 71 that is necessary for the execution of file data stored in the storage 90 or the like. The process 71 generated as above may command the central processing unit 60 to operate and process the data that is addressed by the VA (Virtual Address), and thus the central processing unit 60 may provide the virtual address of the data that is necessary for the operation and processing to the memory management unit 40.

The memory management unit 40, which has received the virtual address from the central processing unit 60, converts the virtual address provided from the central processing unit 60 into a PA (Physical Address) that can be directly referred to on the main memory 10 or a first area 91 of the storage 90 with reference to a page table (not illustrated).

The storage 90 may be provided with a mass storage space in comparison to the main memory 10, and may be implemented by, for example, an MRAM which has both the DRAM characteristic in which electric information can be rapidly taken out and the magnetic recording characteristic in which the information can be kept for a long term, but the present inventive concept is not limited thereto. An example of the storage 90 implemented by the MRAM may be a SSD (Solid State Drive), but the present inventive concept is not limited thereto.

The storage 90 may include the first area 91 and a second area 92. In the first area 91 of the storage 90, m (m is a natural number) code areas having the read-only characteristic related to the performance of the process 71 among the execution files are stored in the form of a binary file. Further, during the initial driving of the SOC system, the memory management unit 40 according to this embodiment refers to a page table (not illustrated) that is updated so that the central processing unit 60 directly accesses n (n is a natural number) predetermined execution files among the m execution files.

For example, during the initial driving of the SOC system, regardless of whether the process 71 related to the m execution files stored in the first area 91 of the storage 90 has been generated, the memory management unit 40 refers to the page table that is updated so that the central processing unit 60 directly accesses code areas of the n predetermined execution files.

Here, the n execution files may be determined by selecting the program that the user frequently uses through the initial setting of the system, or may be determined by the OS 70 through reflection of the system operating situation.

As described above, if the page table (not illustrated) that the memory management unit 40 refers to is updated during the initial driving, the update of the page table (not illustrated) to be performed when the respective execution files are newly performed can be reduced, and thus the operational performance of the SOC system can be further improved.

The second area 92 of the storage 90 according to this embodiment may be used in a similar manner as the storage of the general SOC system according to the above-described embodiment. For example, the second area 92 may store a data area and a BSS area.

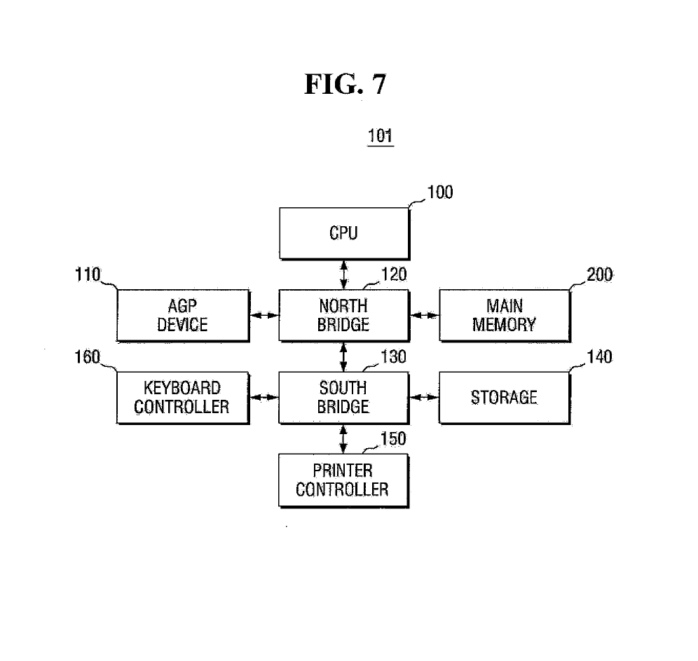

Next, referring to FIG. 7, a computing system that includes the main memory and storage of the SOC system according to an exemplary embodiment of the present inventive concept will be described.

FIG. 7 is a block diagram illustrating a computing system that includes the main memory and storage of the SOC system according to an exemplary embodiment of the present inventive concept.

Referring to FIG. 7, the computing system 101 includes a central processing unit 100, an AGP (Accelerated Graphics Port) device 110, a main memory 200, a storage (for example, SSD, HDD, or the like) 140, a north bridge 120, a south bridge 130, a keyboard controller 160, and a printer controller 150.

The computing system 101 illustrated in FIG. 7 may be a personal computer or a notebook computer. However, the present inventive concept is not limited thereto, and examples of the computing system 101 may be modified accordingly.

In the computing system 101, the central processing unit 100, the AGP device 110, and the main memory 200 are connected to the north bridge 120. However, the present inventive concept is not limited thereto. For example, the north bridge 120 may be included within the central processing unit 100.

In an exemplary embodiment, the AGP is a bus standard that enables 3D graphic expression to be rapidly implemented, and the AGP device 110 may include a video card that reproduces a monitor image.

The central processing unit 100 may perform various kinds of operations that are required to drive the computing system 101, and also execute the OS and application programs.

The main memory 200 may load data that is required to perform the operation of the central processing unit 100 from the storage 140 and store the loaded data therein. An example of a memory that implements the main memory 200 may be a DRAM (Dynamic Random Access Memory), but the present inventive concept is not limited thereto.

The storage 140, the keyboard controller 160, the printer controller 150, and various kinds of peripheral devices (not illustrated) may be connected to the south bridge 130.

The storage 140 is a mass data storage device that stores data, and may be implemented by, for example, HDD or SSD. However, the present inventive concept is not limited thereto. In particular, although the storage 140 according to this embodiment may be implemented by the MRAM which has both the DRAM characteristic in which electric information can be rapidly taken out and the magnetic recording characteristic in which the information can be kept for a long term, the present inventive concept is not limited thereto.

The storage 80 may include the first area in which the code area of the execution file having the read-only characteristic is loaded in the form of a binary file, and the second area in which the data area and the BSS area of the execution file are stored in a file structure. That is, the storage (80 in FIG. 1 or 90 in FIG. 6) of the SOC system according to the above-described embodiments may be adopted as the storage 140 included in the computing system 101 according to this embodiment.

Although it is exemplified that the storage 140 is connected to the south bridge 130 in the computing system 101 according to this embodiment, the present inventive concept is not limited thereto, and the storage 140 may be modified so that it is connected to the north bridge 120 or directly connected to the central processing unit 100.

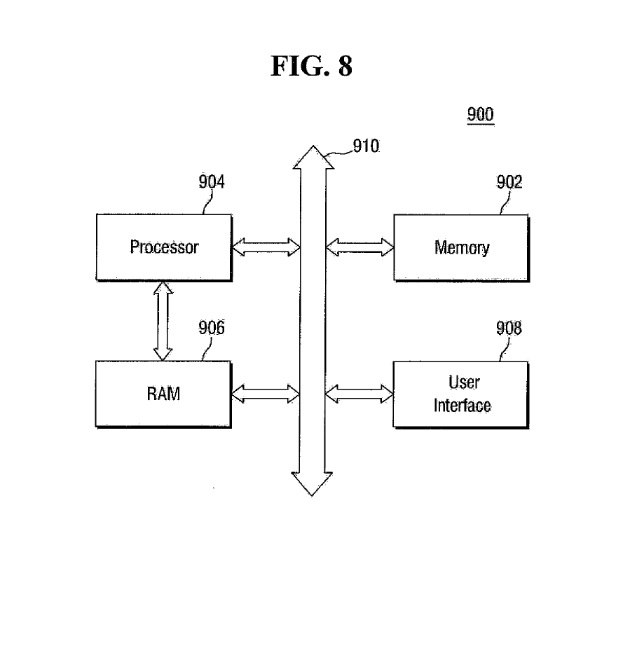

Next, referring to FIG. 8, an electronic system that includes the SOC system according to an exemplary embodiment of the present inventive concept will be described.

FIG. 8 is a block diagram illustrating the configuration of an electronic system that can include the SOC system according to an exemplary embodiment of the present inventive concept.

Referring to FIG. 8, an electronic system 900 includes SOC system according to an exemplary embodiment of the present inventive concept as described above. The electronic system 900 includes a memory system 902, a processor 904, a RAM 906, and a user interface 908.

The memory system 902, the processor 904, the RAM 906, and the user interface 908 perform data communication with each other using a bus 910.

The processor 904 executes programs and controls the electronic system 900, and the RAM 906 may be used as an operating memory of the processor 904. Here, if the electronic system 900 adopts the main memory of the SOC system according to at least one embodiment of the present inventive concept as described above, the processor 904 may correspond to the central processing unit (60 in FIG. 1 and FIG. 6) as described above, and the RAM 906 may correspond to the main memory (10 in FIG. 1 and FIG. 6). The processor 904 and the RAM 906 may be implemented to be packaged into one semiconductor device or a semiconductor package.

The user interface 908 may be used to input/output data to the electronic system 900. The memory system 902 may store codes for the operation of the processor 904, data processed by the processor 904, or data input from the outside. If the electronic system 900 includes the SOC system according to the embodiments of the present invention as described above, the memory system 902 may correspond to the storage (80 in FIGS. 1 and 90 in FIG. 6) as described above.

The memory system 902 may include a separate controller for the operation, and may be configured to additionally include an error correction block. The error correction block may be configured to detect and correct an error of the data stored in the memory system 912 using an error correction code (ECC).

The memory system 902 may be integrated into one semiconductor device. Exemplarily, the memory system 902 may be integrated into one semiconductor device to configure a memory card. For example, the memory system 902 may be integrated into one semiconductor device to configure a memory card, such as a PC card (PCMCIA (Personal Computer Memory Card International Association)), a compact flash (CF) card, a smart media card (SM or SMC), a memory stick, a multimedia card (MMC, RS-MMC, MMCmicro), a SD card (SD, miniSD, microSD, or SDHC), a universal flash storage device (UFS), or the like.

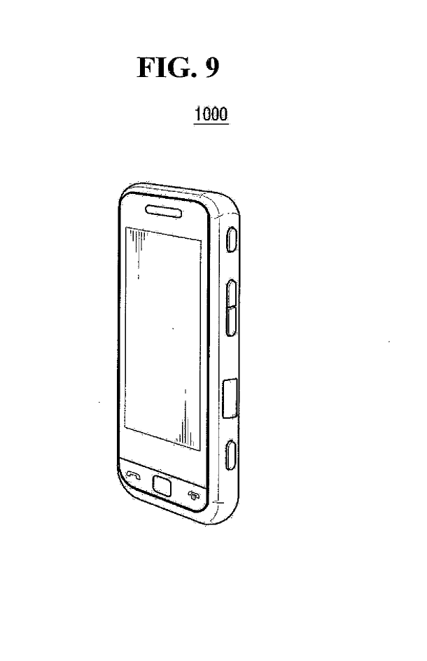

The electronic system 900 illustrated in FIG. 8 may be applied to electronic control devices of various electronic appliances. FIG. 9 is a view illustrating an application example of the electronic system of FIG. 8 applied to a smart phone. In the case where the electronic system (900 in FIG. 8) is applied to a smart phone 1000, the above-described electronic system (900 in FIG. 8) may be, for example, an AP (Application Processor), but the present inventive concept is not limited thereto.

In addition, the electronic system (900 in FIG. 8) may be provided as one of various constituent elements of electronic devices, such as a computer, a UMPC (Ultra Mobile PC), a work station, a net-book, a PDA (Personal Digital Assistants), a portable computer, a web tablet, a wireless phone, a mobile phone, a smart phone, an e-book, a PMP (Portable Multimedia Player), a portable game machine, a navigation device, a black box, a digital camera, a 3-dimensional television receiver, a digital audio recorder, a digital audio player, a digital picture recorder, a digital picture player, a digital video recorder, a digital video player, a device that can transmit and receive information in a wireless environment, one of various electronic devices constituting a home network, one of various electronic devices constituting a computer network, one of various electronic devices constituting a telematics network, an RFID (radio frequency identity) device, or one of various constituent elements constituting a computing system.

Although exemplary embodiments of the present inventive concept have been described for illustrative purposes, those skilled in the art will appreciate that various modifications, additions and substitutions are possible, without departing from the scope and spirit of the invention.

What is claimed is:

1. A SOC system comprising:
a central processing unit;
a memory management unit configured to receive a virtual address from the central processing unit and convert the virtual address into a physical address;
a main memory comprising a volatile memory directly accessed through the physical address converted by the memory management unit; and
a storage comprising a nonvolatile memory separate from the main memory and comprising a first area directly accessed through the physical address converted by the memory management unit,
wherein the first area of the storage is configured to store a code area of an execution file in the form of a binary file and the code area has a read-only characteristic.

2. The SOC system of claim 1, wherein the nonvolatile memory comprises an Magnetic Random Access Memory MRAM, and
the volatile memory comprises a Dynamic Random Access Memory DRAM.

3. The SOC system of claim 1, wherein the storage further comprises a second area,
wherein a data area of the execution file and a BSS area are stored in the second area of the storage.

4. The SOC system of claim 1, further comprising a page table, wherein the memory management unit refers to the page table to convert the virtual address provided from the central processing unit to the physical address,
wherein the page table is updated to enable the central processing unit to directly access the first area of the storage through the page table.

5. The SOC system of claim 4, wherein when the SOC system is initially operated, the page table is pre-updated to enable code areas comprising n predetermined execution files among m execution files stored in the first area of the storage to be referred to, wherein n and m are natural numbers.

6. A method for operating a SOC system, the method comprising:
storing a code area of an execution file in a first area of a storage in the form of a binary file, wherein the storage comprises a nonvolatile memory;
during execution of the execution file, configuring the first area of the storage as an area that can be directly accessed by a central processing unit; and
executing the execution file,
to wherein the code area has a read-only characteristic.

7. The method for operating a SOC system of claim 6, wherein the nonvolatile memory comprises a Magnetic Random Access Memory MRAM.

8. The method for operating a SOC system of claim 6, wherein the executing the execution file comprises the central processing unit directly accessing the first area and executing the execution file stored in the first area of the storage through a memory management unit.

9. The method for operating a SOC system of claim 6, wherein the configuring the first area of the storage as the area that can be directly accessed by the central processing unit comprises updating a page table which a memory management unit refers to.

10. The method for operating a SOC system of claim 9, wherein when the SOC system is initially operated, the page table is pre-updated to enable code areas comprising n predetermined execution files among m execution files stored in the first area of the storage to be referred to, wherein m and n are natural numbers.

11. A SOC system comprising:
a central processing unit (CPU);
a memory management unit (MMU) configured to receive a virtual address from the CPU and convert the virtual address into a physical address;
a translation look aside buffer (TLB) configured to convert the virtual address into a physical address when virtual memory is needed;
a main memory comprising a volatile memory directly accessed through the physical address converted by the MMU; and
a virtual memory comprising a nonvolatile memory comprising a first area directly accessed through the physical address converted by the TLB,
wherein the first area comprises an execution file comprising a computer program comprising instructions executable by the CPU and the first area is read only.

12. The SOC system of claim 11, wherein the nonvolatile memory comprises a second area comprising data used by the computer program, and the second area is read-write.

13. The SOC system of claim 12, further comprising a page table used by the MMU and the TLB to convert a virtual address to a physical address.

14. The SOC system of claim 13, further comprising an operating system that is configured to search a code area of the execution file based on the virtual address for addresses the data needs for an operation, and the operating system updates the page table using the addresses resulting from the search.
